(19) United States
(12) Patent Application Publication
(10) Pub. No.: US 2024/0219481 A1
(43) Pub. Date: Jul. 4, 2024

(54) APPARATUSES, SYSTEMS, AND METHODS FOR SCREENING ELECTRONIC COMPONENTS

(71) Applicant: Schneider Electric USA, Inc., Andover, MA (US)

(72) Inventors: Juan Ignacio Melecio Ramirez, North Liberty, IA (US); Collin Richard Fischels, Independence, IA (US); Kenneth Riehl, North Liberty, IA (US); Jeremy D. Schroeder, Cedar Rapids, IA (US)

(73) Assignee: Schneider Electric USA, Inc., Boston, MA (US)

(21) Appl. No.: 18/539,141

(22) Filed: Dec. 13, 2023

Related U.S. Application Data
(60) Provisional application No. 63/436,456, filed on Dec. 30, 2022.

(51) Int. Cl. G01R 31/62; G01R 1/04; G01R 31/52

(52) U.S. Cl. CPC G01R 31/62; G01R 1/0416; G01R 31/52

(57) ABSTRACT

A system may include a device under test, a body having a plurality of conductors, a rotation section, a probe associated with the rotation section, the probe configured to house at least a portion of one or more of the plurality of conductors, and a nest having at least one terminal, the nest configured to couple to the device under test and to permit at least a portion of the probe to pass through an opening of the device under test.

### CROSS-REFERENCE TO RELATED APPLICATIONS

This application claims priority to and the benefit of U.S. Provisional Application No. 63/436,456, filed Dec. 30, 2022, the entire contents of which are herein incorporated by reference in their entirety.

### FIELD

This disclosure relates to testing (e.g., screening) electrical components. More specifically, this disclosure relates to apparatuses, systems, and methods for screening sensors for ground fault applications.

### BACKGROUND

Conventional systems utilize complex and costly device manufacturing and component testing processes. For example, individual electronic components of a device might not be tested until the device is fully assembled, thereby creating high rates of inspection failure for assembled devices. Further, there can be high levels of inconsistency for ground fault detection for high winding asymmetry under handle rated load conditions using existing testing systems. Costs and timing associated with testing circuit breaker sensors and assembled circuit breaker devices is significantly increased by operations and costs associated with reworking and scrapping devices and components based upon test failures only detected at the end of a manufacturing process.

Such conventional methods and systems have generally been considered satisfactory for their intended purpose. However, there is still a need in the art for improvements. This disclosure provides a solution for this need.

### SUMMARY

Implementations consistent with this disclosure may provide a system for screening an electronic component. The system may include a device under test, a body having a plurality of conductors, a rotation section, a probe associated with the rotation section, the probe configured to house at least a portion of one or more of the plurality of conductors, and a nest having at least one terminal, the nest configured to couple to the device under test and to permit at least a portion of the probe to pass through an opening of the device under test. The rotation section may rotate the probe within the opening of the device under test. The rotation section may include an eccentric section, which receives at least one of the plurality of conductors and which is configured to be placed adjacent to the device under test during a screening operation. The eccentric section may include a plurality of notches at an outer surface configured to receive at least a portion of at least one of the plurality of conductors. The eccentric section may include at least one groove associated with at least one of the plurality of notches, the at least one groove configured to receive at least a portion of at least one of the plurality of conductors. The plurality of notches may include two notches, and the at least one groove may include two grooves. The system further includes a rail, the rail configured to couple to the nest and further configured to translate movement of the nest relative to the probe. The device may be a current transformer having at least one winding. A voltage associated with at least one winding of the current transformer may be measured as the probe rotates within the opening of the device under test. A rotation mechanism may be coupleable to at least one of the rotation section or the probe, the rotation mechanism configured to cause the probe to rotate or translate relative to the device under test. The system can include a test module configured to receive voltage signals from the current transformer to determine whether the current transformer is functioning within a set threshold as the prob rotates.

According to further aspects of this disclosure, provided is an apparatus for screening a device under test. The apparatus includes a body having a plurality of conductors, a rotation section, a probe associated with the rotation section, the probe configured to house at least a portion of one or more of the plurality of conductors, and a nest having at least one terminal, the nest configured to couple to the device under test. The rotation section may rotate the probe during a screening operation. The rotation section may include an eccentric section configured to receive at least one of the plurality of conductors. The eccentric section may include a plurality of notches at an outer surface configured to receive at least a portion of at least one of the plurality of conductors. The eccentric section may include at least one groove associated with at least one of the plurality of notches, the at least one groove configured to receive at least a portion of at least one of the plurality of conductors. The plurality of notches may include two notches, and the at least one groove may include two grooves. The apparatus may include a rail configured to couple to the nest and further configured to translate movement of the nest relative to the probe.

According to further aspects of this disclosure, provided is a method for screening an electronic component. The method includes manufacturing an assembly, performing wire distribution testing on the assembly, forming a device by building a Printed Circuit Board Assembly (PCBA) including the assembly a combining the PCBA with a housing, and executing an end of line test on the device. The wire distribution testing may include activating a rated current, initiating a measurement operation, obtaining measurement data in relation to the assembly, ending the measurement operation and turning off the rated current, determining a device attribute associated with the assembly, and comparing the device attribute to at least one threshold value to determine whether the assembly is acceptable. Obtaining measurement data in relation to the assembly may include rotating a probe and/or rotation section of testing device within an opening of the assembly while a rated current is passed through at least one conductor within the probe. Obtaining measurement data in relation to the assembly may include obtaining measurement data responsive to an eccentric portion of the probe containing at least one conductor, the eccentric portion of the probe rotating adjacent to the assembly.

Numerous other objects, features, and advantages of the present invention will be readily apparent to those skilled in the art upon a reading of the following disclosure when taken in conjunction with the accompanying drawings

These and other features of the embodiments of the subject disclosure will become more readily apparent to those skilled in the art from the following detailed description taken in conjunction with the drawings.

### BRIEF DESCRIPTION OF THE DRAWINGS

So that those skilled in the art to which the subject disclosure appertains will readily understand how to make and use the devices and methods of the subject disclosure without undue experimentation, embodiments thereof will be described in detail herein below with reference to certain figures, wherein:

FIG. 1A illustrates an embodiment of a partial internal view of a device according to aspects of this disclosure.

FIG. 1B illustrates a partial internal view of an alternative embodiment of a device according to aspects of this disclosure.

FIG. 2A illustrates a side view of an embodiment of a sensor component according to aspects of this disclosure.

FIG. 2B illustrates a raised side perspective view of an alternative embodiment of a sensor component according to aspects of this disclosure.

FIG. 3 illustrates a partial block view of a testing system according to aspects of this disclosure.

FIG. 4A illustrates a first part of a flowchart providing a method of testing a sensor component according to aspects of this disclosure.

FIG. 4B illustrates a second part of the flowchart of FIG. 4A for providing a method of testing a sensor component according to aspects of this disclosure.

FIG. 5 illustrates four examples of winding distribution of a sensor component according to aspects of this disclosure.

FIG. 6 illustrates a schematic diagram of an arrangement having a current transformer with a non-uniform coil wrapped around a core, and three conductors passing through the core opening also causing wrap-around effects.

FIG. 7 illustrates a partial diagram of an embodiment of a schematic of a probe of a test structure including a current loop according to aspects of this disclosure.

FIG. 8 illustrates a partially transparent view of an embodiments of a testing system during movement of a sensor component under test according to aspects of this disclosure.

FIG. 9 illustrates a partial raised front perspective view of a testing system according to aspects of this disclosure.

FIG. 10A illustrates a partial rear perspective view of a rotation section of a testing system according to aspects of this disclosure.

FIG. 10B illustrates a partial top perspective view of a rotation section of the testing system according to aspects of this disclosure.

FIG. 11 illustrates a partial view of a sequence of testing a sensor component at a testing system according to aspects of this disclosure.

FIG. 12 illustrates an embodiment of a process for testing a sensor component according to aspects of this disclosure.

FIG. 13 illustrates a process for determining test performance of a sensor component according to aspects of this disclosure.

FIG. 14 illustrates an embodiment of a waveform generated in association with a sensor component tested according to aspects of this disclosure.

FIG. 15 illustrates a partial diagram of an alternative embodiment of a probe useable with a testing system according to aspects of this disclosure.

FIG. 16A illustrates an example of a waveform generated in association with a sensor component under test using the current loop of the testing system illustrated by FIG. 15 according to aspects of this disclosure.

FIG. 16B illustrates an example of a waveform generated in association with a sensor component under test using the current loop of the testing system illustrated by FIG. 7 according to aspects of this disclosure.

FIG. 17A illustrates an example of a waveform generated in association with a sensor component under test using the current loop of the testing system illustrated by FIG. 15 according to aspects of this disclosure.

FIG. 17B illustrates an example of a waveform generated in association with a sensor component under test using the current loop of the testing system illustrated by FIG. 7 according to aspects of this disclosure.

FIG. 18 illustrates a partial raised view of an embodiment of a testing system according to aspects of this disclosure.

### DETAILED DESCRIPTION

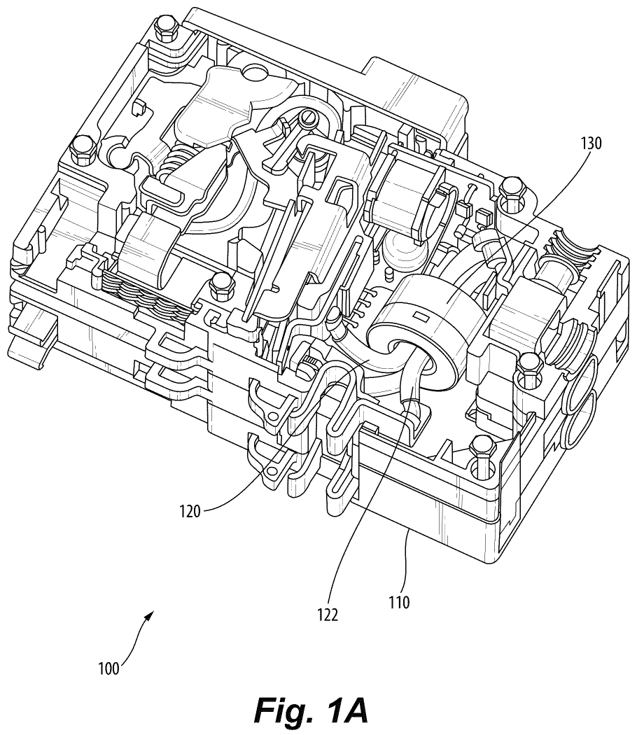

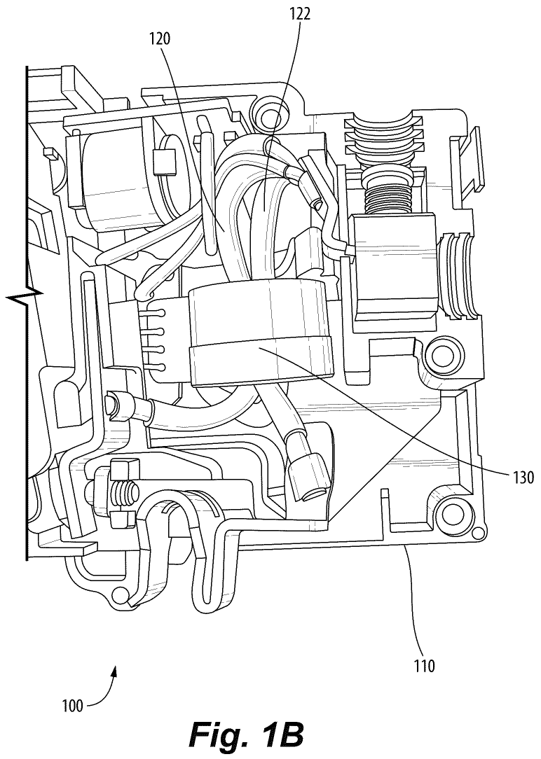

Reference will now be made to the drawings wherein like reference numerals identify similar structural features or aspects of the subject disclosure. For purposes of explanation and illustration, and not limitation, an illustrative view of an embodiment of a device in accordance with the disclosure is shown in FIGS. 1A and 1s designated generally by reference character 100. Other views, embodiments, and/or aspects of this disclosure are illustrated in FIGS. 1B-18. Aspects of this disclosure may provide apparatuses, systems, and methods for screening electronic components.

FIG. 1A illustrates an embodiment of a partial internal view of a device according to aspects of this disclosure. A device 100 may include a housing 110 containing a first conductor 120 (e.g., a line, neutral, or ground), a second conductor 122 (e.g., a line, neutral, or ground), and/or a current transformer (CT) 130. The device 100 may be a device or portion thereof configured to perform at least one operation. The device 100 may be a Miniature Circuit Breaker (MCB), a Ground Fault Circuit Interrupter (GFCI), or other electronic device or portion thereof in various embodiments or may be a device or portion of device configured to perform one or more operations corresponding to a GFCI. At least a portion of the first conductor and/or second conductor 122 may be configured to pass through an opening of the CT 130 (e.g., at an opening 140 of the CT 130 as described herein). Although illustrated with three conductors in FIG. 1, it should be appreciated that any number of conductors may be configured to pass through at least a portion of an opening of the CT 130 in various embodiments without departing from the spirit and scope of this disclosure. The CT 130 can be any suitable shape (e.g., a polygonal closed shape, e.g., a rectangular closed shape). For example, the CT 130 can be a circular or toroidal closed shapes as shown.

FIG. 1B illustrates a partial internal view of an alternative embodiment of a device according to aspects of this disclosure. Like the device 100 of FIG. 1A, the device 100 of FIG. 1B may include a housing 110 containing a first conductor 120 (e.g., a line, neutral, or ground), a second conductor 122 (e.g., a line, neutral, or ground), and/or a current transformer (CT) 130 (e.g., assembly). The device 100 may be a device or portion thereof configured to perform at least one operation. The device 100 may be a GFCI or portion thereof in various embodiments or may be a device or portion of device configured to perform one or more operations corresponding to a GFCI. At least a portion of the first conductor and/or second conductor 122 may be configured to pass through an opening of the CT 130 (e.g., at an opening 140 of the CT 130 as described herein). Although illustrated with three conductors in FIG. 1B, it should be appreciated that any number of conductors may be configured to pass through at least a portion of an opening of the CT 130 in various embodiments without departing from the spirit and scope of this disclosure.

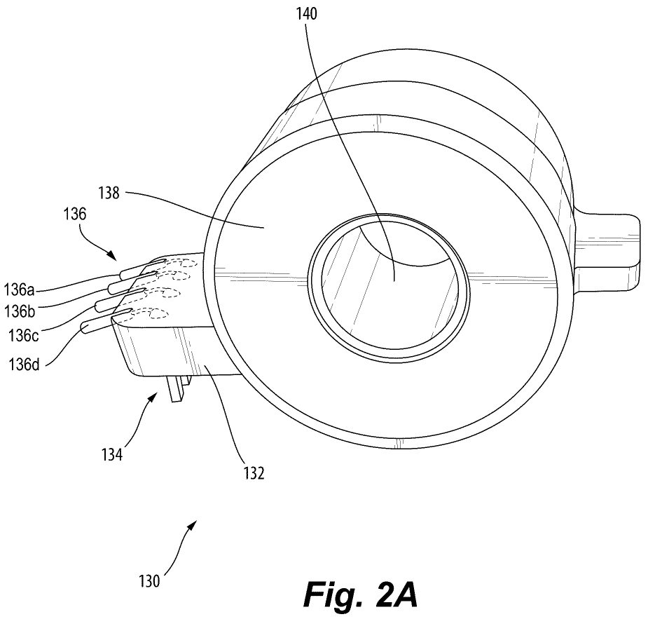

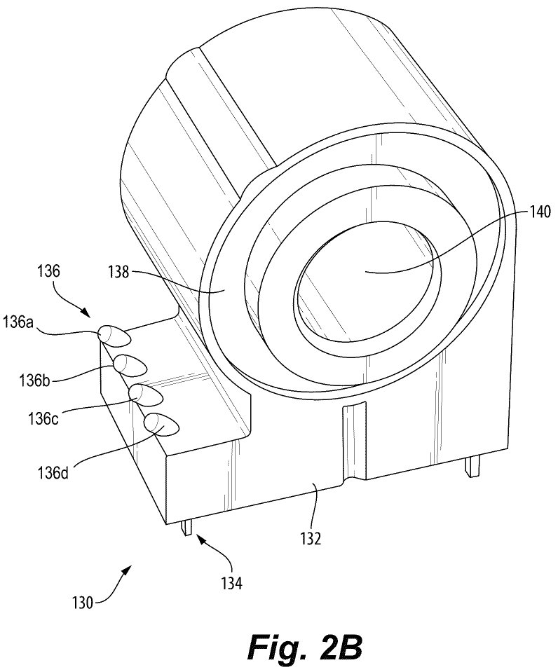

FIG. 2A illustrates a side view of an embodiment of a sensor component according to aspects of this disclosure. In certain embodiments, the CT 130 of FIG. 2A corresponds to the device 100 of the types illustrated by FIGS. 1A and/or 1B and includes one or more of a body 132, a first terminal 134 (e.g., having a plurality of pins extending downward), a second terminal 136 (e.g., having first, second, third, and fourth pins 136a, b, c, d, respectively), a coil housing 138, and/or an opening 140. In certain embodiments, the first terminal 134 and the second terminal 136 may include a plurality of pins in various embodiments. The first terminal 134 and the second terminal 136 may be connected together such that each pin 136a, b, c, d of the second terminal 136 is connected to a respective pin of the first terminal 134. In certain embodiments, the first pin 136a and the second pin 136b can be connected to opposing ends of a sense coil contained within the housing 110 of the CT 130, for example at the coil housing 138 thereof. The opening 140 of the CT 130 may be configured to permit one or more conductors (e.g., first conductor 120, second conductor 122, and/or other conductor(s) or components (or portions thereof)) to pass at least partially therethrough. The first conductor 120 and the second conductor 122 can pass through the opening 140, for example. Any suitable number of conductors for any suitable application are contemplated herein (e.g., three as shown). In accordance with at least one aspect of this disclosure, a device 100 can include a line conductor, a neutral conductor, and/or a current transformer, for example as disclosed herein. The CT 130 can include a sense coil wrapped around a core configured to magnetically couple to a line conductor and a neutral conductor passing through the opening 140. The device 100 can include a test coil partially wrapped around the core and configured to magnetically couple to the sense coil through the core to provide a test signal to the sense coil. The CT 130 of FIG. 2A can include a first, second, and/or third shield in various embodiments.

FIG. 2B illustrates a raised side perspective view of an alternative embodiment of a sensor component according to aspects of this disclosure. The CT 130 illustrated by FIG. 2B includes one or more of a body 132, at least one first terminal 134, at least one second terminal 136, a coil housing 138, and/or an opening 140. As described above with respect to FIG. 2A, pins of a the second terminal 136 (and respective connected pins of the first terminal 134) may be connected to opposing ends of a sense coil contained within the housing 110 of the CT 130, for example at the coil housing 138 thereof. The opening 140 of the CT 130 may be configured to permit one or more conductors (e.g., first conductor 120, second conductor 122, and/or other conductor(s) or components (or portions thereof)) to pass at least partially therethrough. A first conductor 120 and a second conductor 122 can pass through the opening 140, for example. Any suitable number of conductors for any suitable application are contemplated herein (e.g., three). In accordance with at least one aspect of this disclosure, a device 100 can include a line conductor, a neutral conductor, and/or a current transformer, for example as disclosed herein. The CT 130 can include a sense coil wrapped around a core configured to magnetically couple to a line conductor and a neutral conductor passing through the opening 140. The device 100 can include a test coil partially wrapped around the core and configured to magnetically couple to the sense coil through the core to provide a test signal to the sense coil. The CT 130 of FIG. 2B can include a first, second, and/or third shield in various embodiments.

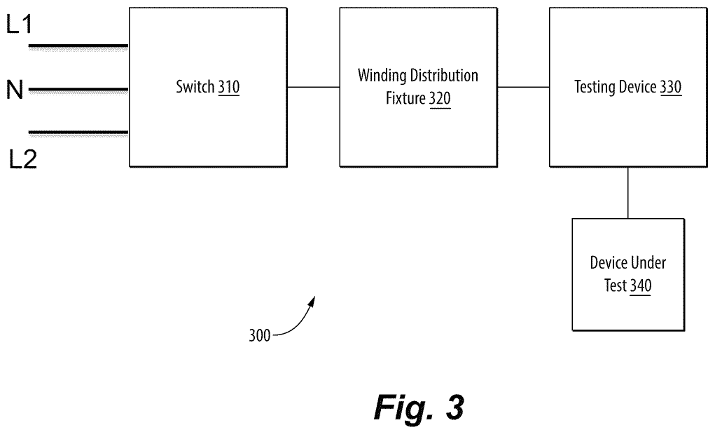

FIG. 3 illustrates an embodiment of a partial block view of a testing system according to aspects of this disclosure. The system 300 includes one or more of a switch 310, a winding distribution fixture 320, a testing device 330, and/or a device under test 340. Two or more of the switch 310, the winding distribution fixture 320, the testing device 330, and/or the device under test 340 may be coupleable to one another using one or more physical and/or conductive interconnections or coupling element(s). The device under test 340 may be a CT 130 in various embodiments. Additionally or alternatively, the device under test 340 may include a device 100 in various embodiments. The system 300 may implement the switch 310 to switch between a plurality of testable current paths for a device under test 340. The winding distribution fixture 320 may be used to provide specific routing of a desired current path.

A current source can be connected to a switch 310, to switch between the combination of lines L1-N, L2-N or L1-L2. A connection of any pairs of lines of the current source can create a current flow on the current path, creating a different combination of magnetic fields inside the DUT, which can generate different output voltages from the DUT 340, that at the end can be compared with a defined limit. In certain embodiments, if any of the voltages generated by any of the combinations is below the limit, the DUT 340 passes the test.

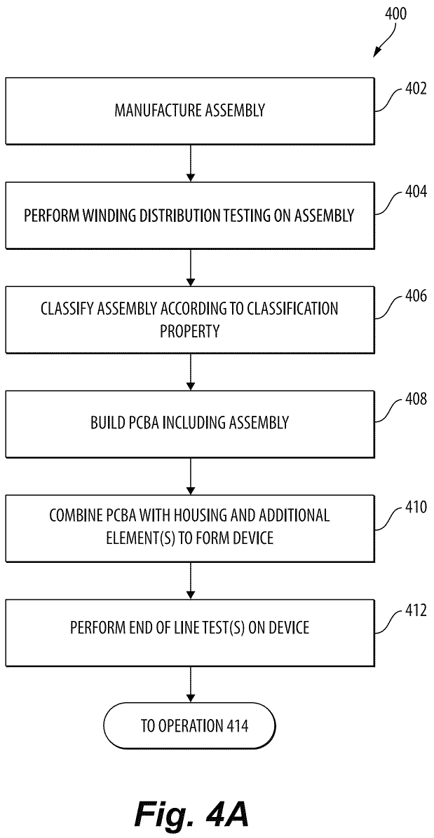

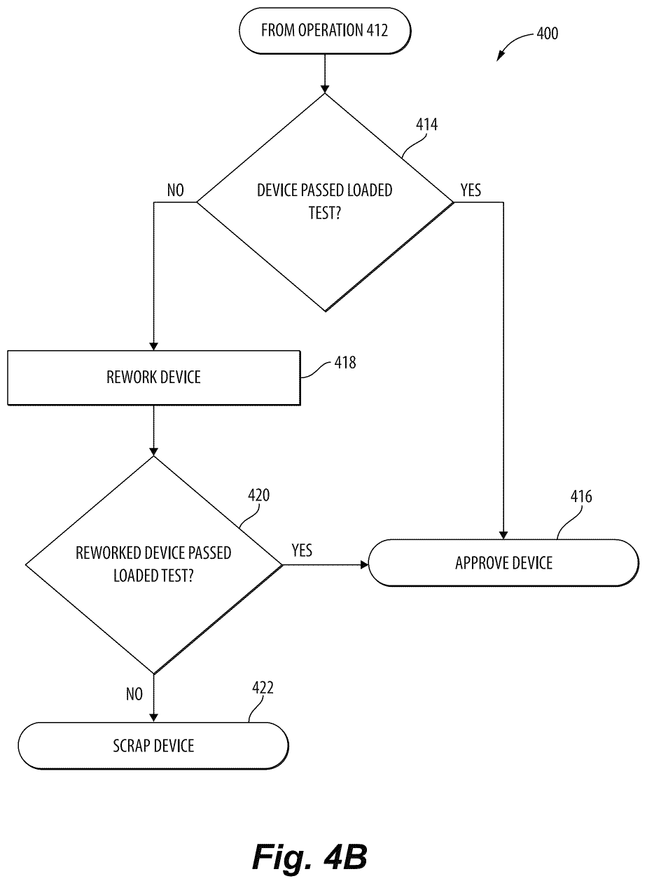

FIG. 4A illustrates a first part of a flowchart providing a method of testing a sensor component according to aspects of this disclosure according to a current system. The method 400 includes an operation 402 where an assembly is manufactured. This may include manufacturing a CT 130 and/or element associated therewith. A wire distribution test may be performed on the assembly at an operation 404. The tested assembly may be classified according to a classification property at an operation 406. A Printed Circuit Board Assembly (PCBA) including the assembly may be built at an operation 408. The PCBA may be combined with a housing and optionally one or more additional elements at an operation 410 to form a device (e.g., GFI MCB). One or more end of line tests may be performed on the device at an operation 412. For example, one or more ground fault test(s) may be performed: a GFI MCB may be loaded with ground fault currents to determine that the behavior is under one or more design specifications and/or thresholds.

The process may then continue to an operation 414 illustrated by FIG. 4B. FIG. 4B illustrates a second part of the flowchart of FIG. 4A for providing a method of testing a sensor component according to aspects of this disclosure. It is determined at an operation 414 whether the device passed the loaded test(s). If it is determined that the device passed the loaded test(s), then the process continues to an operation 416 where the device is approved. If, however, it is determined at operation 414 that the device did not pass the loaded test(s), the process continues to an operation 416 where the device is reworked. The reworked device is then used to perform loaded test(s) at an operation 420. If it is determined that the reworked device passed the loaded test at operation 420, the process continues to operation 416 where the device is approved. However, if it is determined at operation 420 that the reworked device did not pass the loaded test(s), the reworked device is scrapped at an operation 422.

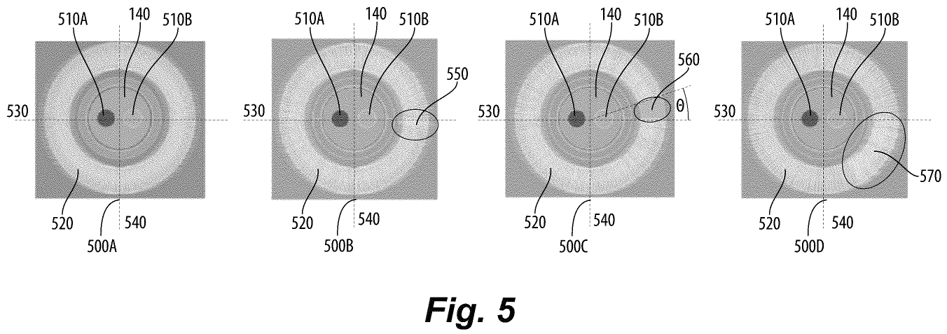

FIG. 5 illustrates four examples of winding distribution of a sensor component according to aspects of this disclosure. FIG. 5 illustrates four examples of sensor component winding distributions, 500A, 500B, 500C, and 500D. Winding distribution may refer to a geometrical distribution of the total number of turns around a transformer's core (e.g., 360 degrees). In various embodiments, a sense winding may include 176 turns, although other numbers of turns may be implemented in various embodiments without departing from the spirit and scope of this disclosure. A uniform distribution such as the one illustrated by winding distribution example 500A may be considered a healthy case, whereby there are an equal number of turns in each of the transformer's sections. Winding distribution examples 500B, 500C, and 500D reflect non-uniform distributions having different numbers of turns in each transformer section. Winding distribution example 500A includes an opening 140 of a CT 130 having a first conductor 510A and a second conductor 510B passing therethrough. A winding section 520 of the CT 130 surrounds at least a portion of the opening 140 and first conductor 510A and second conductor 510B therein. A horizontal axis 530 and a vertical axis 540 are provided for reference. The winding section 520 of winding distribution example 500A provides an evenly distributed winding configuration, without any overlapping wiring sections or missing wiring sections. Winding distribution example 500B reflects a winding section 520 having a winding overlap section 550. Winding distribution example 500C reflects a winding section 520 having a missing wiring section 560 at an angle range θ from the horizontal axis 530. The angle θ of winding distribution example 500C is 17 degrees, although any angle value may exist for one or more CTs. Winding distribution example 500D reflects a winding section 520 having a large winding overlap section 570 extending nearly from the horizontal axis 530 to the vertical axis 540.

FIG. 6 illustrates a schematic diagram of an arrangement having a current transformer with a non-uniform coil wrapped around a core, and three conductors passing through the core opening also causing wrap-around effects. FIG. 6 illustrates a partial depiction of an element of a sensor component having a plurality of current paths passing therethrough according to aspects of this disclosure. The depiction of a device 600 includes an example of a winding section of a CT having a plurality of conductors passing through an opening thereof, along with corresponding wrap-around effects. FIG. 6 depicts a device 600 with current flowing in L1 and L2, where I1=I2. FIG. 6 illustrates an example of a CT having non-uniform and random winding distribution and effect(s) from nearby conductors.

The effect of coils' random distribution in combination with the magnetic influence of nearby conductors (wrap around effect) results in an output voltage, Vout, with a magnitude different to zero. Vout can have a considerably higher value compared to the ideal case (uniform winding distribution) presented previously. Vout is the result of the sum of each coil's fem (e.g., as a result of induced current, each one with either positive sign or negative magnitude) and each coil's contribution highly depends on its physical location around the core and with respect to the L1, L2, or N conductors. To assess the influence of nearby conductors and degree of asymmetry on the CT toroidal transformers, a new and improved winding distribution screening method is provided herein. Embodiments can be applied to any suitable CT closed shape (e.g., a polygonal closed shape, e.g., a rectangular closed shape), not just circular/toroidal shapes.

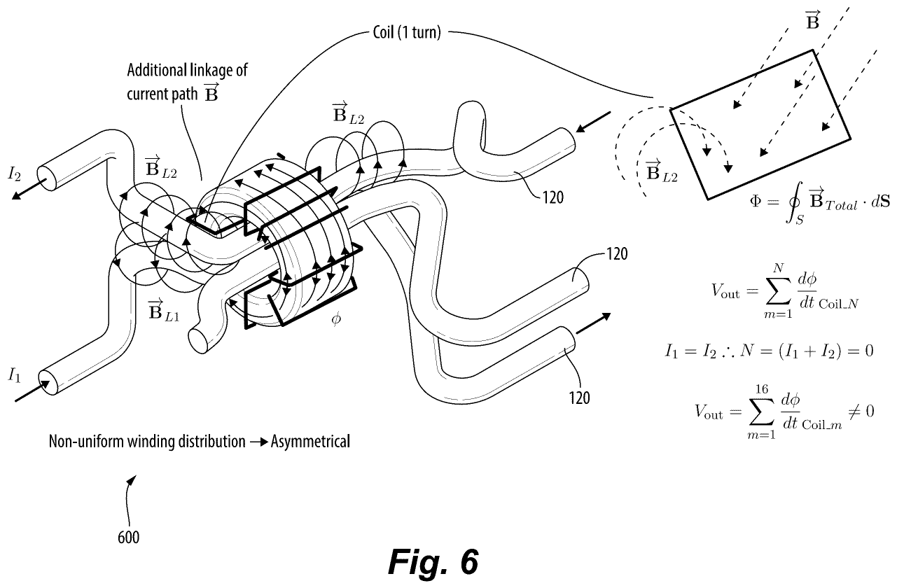

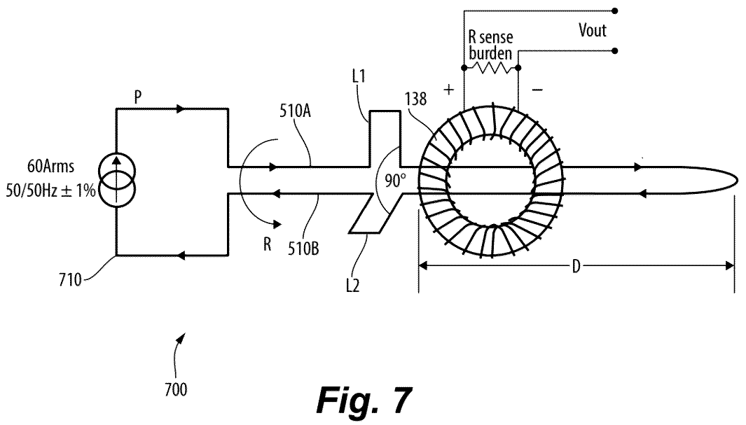

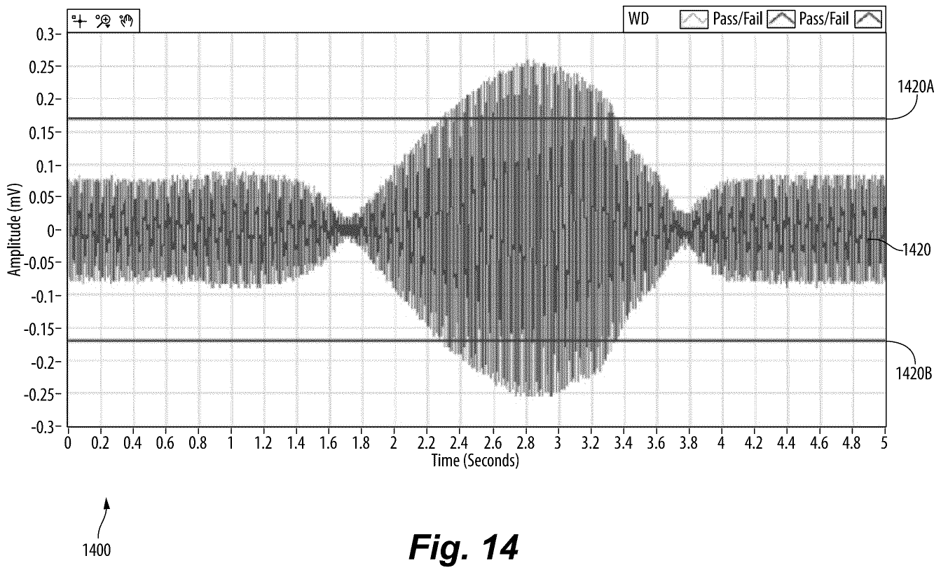

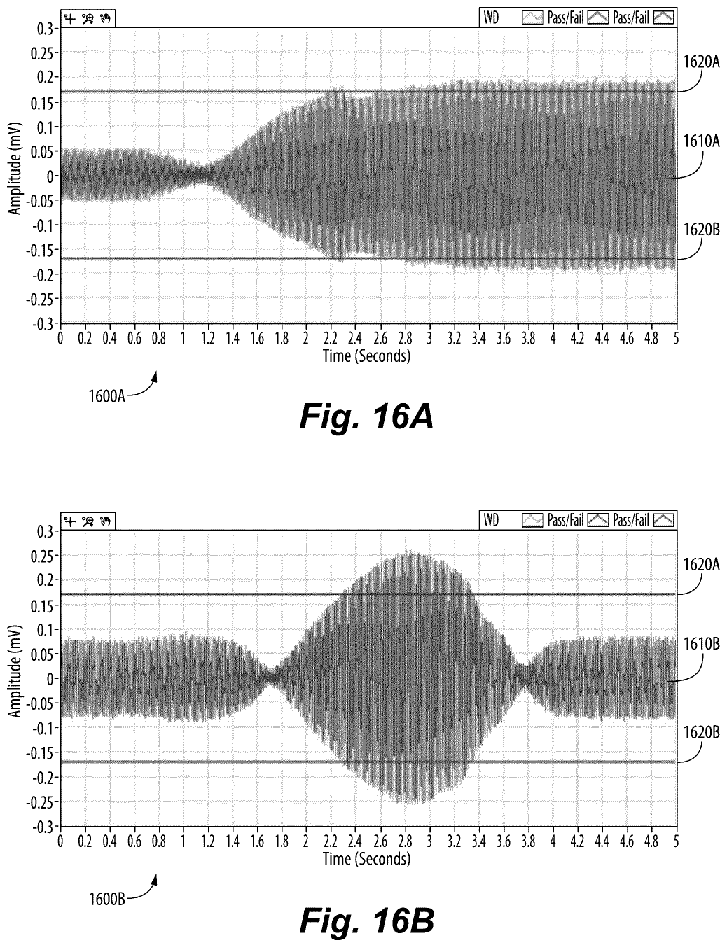

FIG. 7 illustrates a partial diagram of an embodiment of a schematic of a probe of a test structure including a current loop according to aspects of this disclosure. The probe illustrated by FIG. 7 may be usable in various embodiments for evaluating winding distribution effects and wrap-around effects. The structure 700 may include one or more of a current loop 710 coupleable to a current source (e.g., a 60 ARMS current source having a frequency of 50/60 Hz+/−1%, although other current sources may be used without departing from the spirit and scope of this disclosure). At least a portion of the current loop 710 may be contained within a probe section of the testing system. The first conductor 510A and second conductor 510B may form or otherwise be coupleable to at least a portion of the current loop 710. A testing structure useable with this disclosure may be configured to rotate the current loop in a rotation direction R during testing (e.g., counterclockwise rotation direction, although any rotation direction may be used within the scope of this disclosure). At least a portion of the current loop 710 may be configured to pass through the coil housing 138 of a CT 130, for example at an opening 140 thereof. A sense resistor Rsense_burden may be couple to at least one winding of the coil housing 138 (e.g., via first pin 136a and second pin 136b as described above with respect to FIG. 2A) and may be used to measure an output voltage associated with the at least one winding of the CT 130. In certain embodiments, the system 700 can include a test module 701 configured to receive voltage signals from the current transformer 138 to determine (e.g., automatically) whether the current transformer 138 is functioning within a set threshold (e.g., as shown in FIGS. 14, 16A, and 16B) as the prob rotates. The test module 701 can output a pass or fail signal for example, based on the voltage signals. In certain embodiments, the voltage feedback can be plotted or otherwise reported to a user or other system, and be read manually or in any other manner (e.g., using artificial intelligence or machine learning).

The current loop may be provided within a plurality of paths of the testing device, for example first eccentric path L1 and second eccentric path L2. These paths may be configured to extend outwardly in a perpendicular direction from a longitudinal direction of the current loop and within a testing distance D extending from the coil housing 138 to an outer extent of the current loop 710. The first eccentric path L1 and the second eccentric path L2 may be configured at 90-degree angles from one another in various embodiments, although alternative angles may be used without departing from the spirit and scope of this disclosure.

Winding distribution screening can have an objective of verifying a sensor's output voltage deviation (quantification of Vout magnitude as in a randomly distributed winding≠0V) under the presence of a balanced current (e.g., 60 A) flowing out through and returning through the center of the current transformer (current loop). Implementations consistent with this disclosure may replicate the effect of the current path wrap effects over the CT.

Wrap around effects screening may be configured to mimic the effects of the current path over the CT. An eccentric probe may be provided with two conductors can rotate and creates an electromagnetic effect over the CT. The CT then varies its output voltage depending on the location of the conductors at any time and the random asymmetric winding. This screening has the possibility of checking the winding distribution and the wrap around effects at the same time on the CT. The process has an objective of finding a maximum Vout during a 360-degree rotation of the rotation section 922 and checking that the Vout voltage is below a defined limit (e.g., Fail/Pass criteria).

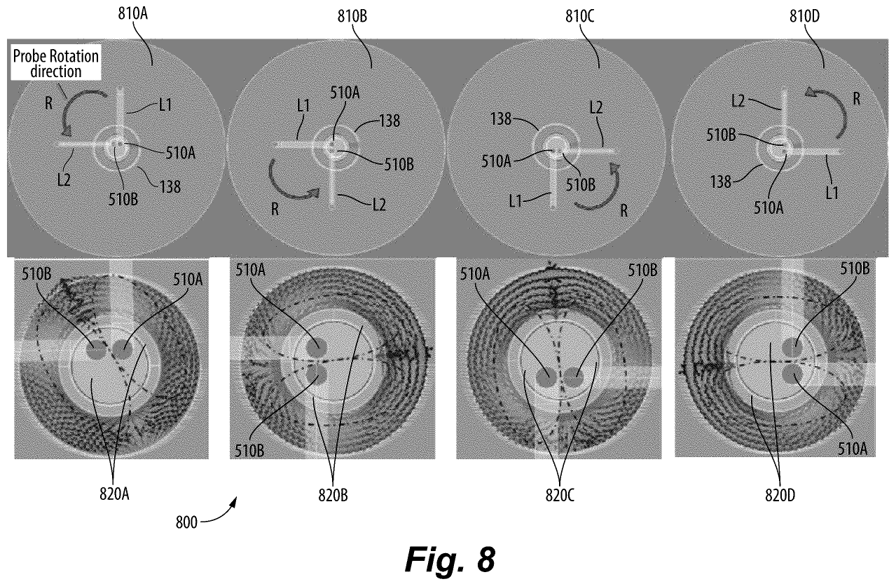

FIG. 8 illustrates a partially transparent view of an embodiments of a testing system during movement of a sensor component under test according to aspects of this disclosure. FIG. 8 provides a cross-sectional view of the embodiment of FIG. 7 in use, showing a probe rotation and dual conductor position within CT 130 under test at four different positions. First position 810A corresponds to a probe position where first eccentric path L1 and second eccentric path L2 are at a first position relative to a testing device and coil housing 138 of a CT 130 under test. The first conductor 510A and the second conductor 510B may pass through an opening (e.g., opening 140) of the CT 130 under test. Magnetic flux lines 820A may be generated by the first conductor 510A and the second conductor 510B during operation, and an output voltage Vout corresponding to at least one winding of the CT 130 may be generated responsive to relative positions of the first conductor 510A, the second conductor 510B, the first eccentric path L1, and/or the second eccentric path L2 adjacent to one or more windings of the coil housing 138. The output voltage Vout corresponding to one or more windings of the CT 130 under test may be measured, for example across the sense resistor Rsense_burden described herein. The probe including at least a portion of the current loop 710 may be configured to rotate in the rotation direction R from the first position 810A to a second position 810B (e.g., 90-degrees from the first position 810A). The second position 810B may result in magnetic flux lines 820B being generated by the first conductor 510A and the second conductor 510B during operation, and an output voltage Vout corresponding to at least one winding of the CT 130 may be generated responsive to relative positions of the first conductor 510A, the second conductor 510B, the first eccentric path L1, and/or the second eccentric path L2 adjacent to one or more windings of the coil housing 138. The output voltage Vout corresponding to one or more windings of the CT 130 under test may be measured, for example across the sense resistor Rsense_burden described herein.

The probe including at least a portion of the current loop 710 may be configured to rotate in the rotation direction R from the second position 810B to a third position 810C (e.g., 90-degrees from the second position 810B). The third position 810C may result in magnetic flux lines 820C being generated by the first conductor 510A and the second conductor 510B during operation, and an output voltage Vout corresponding to at least one winding of the CT 130 may be generated responsive to relative positions of the first conductor 510A, the second conductor 510B, the first eccentric path L1, and/or the second eccentric path L2 adjacent to one or more windings within the coil housing 138. The output voltage Vout corresponding to one or more windings of the CT 130 under test may be measured, for example across the sense resistor Rsense_burden described herein. The probe including at least a portion of the current loop 710 may be configured to further rotate in the rotation direction R from the third position 810C to a fourth position 810D (e.g., 90-degrees from the third position 810C). The fourth position 810D may result in magnetic flux lines 820D being generated by the first conductor 510A and the second conductor 510B during operation, and an output voltage Vout corresponding to at least one winding of the CT 130 may be generated responsive to relative positions of the first conductor 510A, the second conductor 510B, the first eccentric path L1, and/or the second eccentric path L2 adjacent to one or more windings within the coil housing 138. The output voltage Vout corresponding to one or more windings of the CT 130 under test may be measured, for example across the sense resistor Rsense_burden described herein.

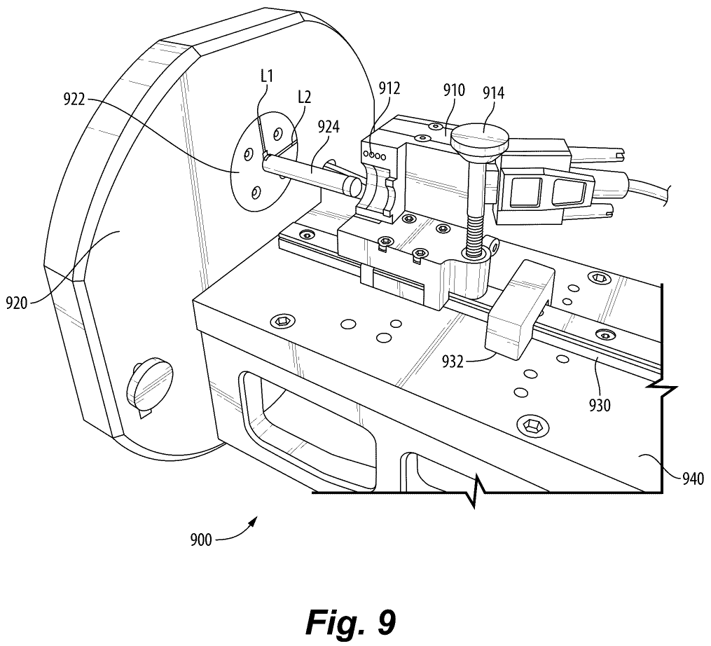

FIG. 9 illustrates a partial raised front perspective view of a testing system according to aspects of this disclosure. The testing system 900 includes one or more of a nest 910, a body 920, a rail 930, and/or a base 940. The body 920 may include a rotation section 922 configured to rotate (e.g., to rotate the current path). The rotation section 922 may be configured to rotate the first eccentric path L1 and/or the second eccentric path L2 in various embodiments. At least a portion of the first conductor 510A and/or the second conductor 510B may be coupleable to the rotation section 922, at least a portion of which may be optionally configured to pass through a notch or opening of the rotation section 922 (e.g., at an outer surface thereof). The nest 910 may include a terminal section 912 configured to be placed in contact with a CT 130 under test, for example at a first terminal 134 and/or a second terminal 136 thereof (e.g., to connect the CT 130 to the Rsense_burden resistor and the test module 701). The nest 910 may further include a position enablement section 914 configured to permit the nest 910 or portion thereof the be selectively enabled and/or prevented from movement along the rail 930. A probe 924 may extend outwardly from the body 920, for example at the rotation section 922 thereof. The first conductor 510A and/or second conductor 510B may be configured to be placed within the probe 924. At least a portion of the probe 924 may be configured to pass at least partially though an opening 140 of a CT 130. The rail 930 may be coupleable to the base 940. The rail 930 and/or base 40 may have coupleable thereto a stop section 932 configured to prevent movement of the nest 910 along the rail 930.

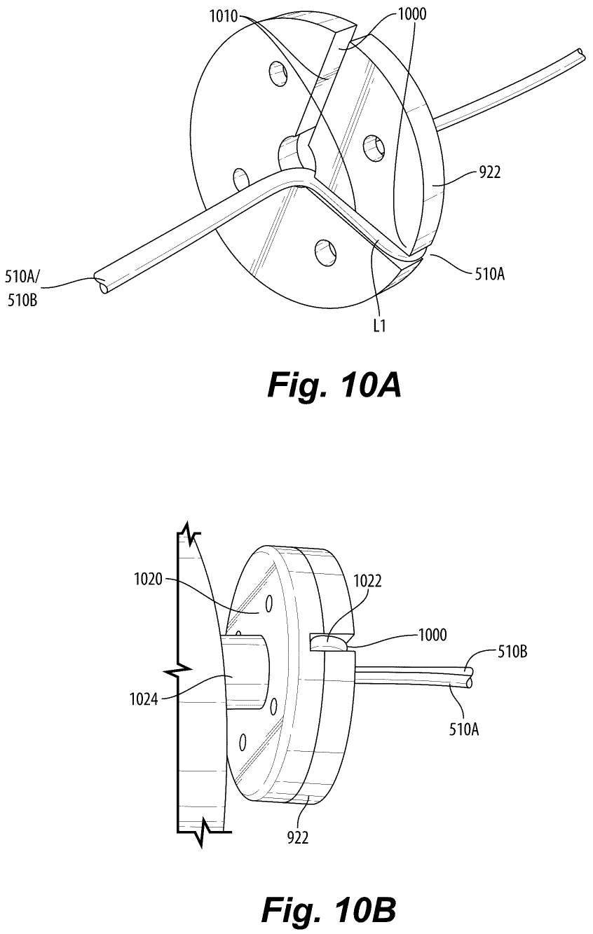

FIG. 10A illustrates a partial rear perspective view of a rotation section of a testing system according to aspects of this disclosure. The rotation section 922 may include one or more grooves 1010 at an outer surface and may be configured to at least partially house one or more of the first eccentric path L1 and/or second eccentric path L2. One or more notches 1000 may be provided at an outer surface of the rotation section 922 and configured to receive one or more of the first eccentric path L1 and/or second eccentric path L2. At least one notch 1000 may be configured to be associated with a groove 1010 in various embodiments, such as that illustrated by FIG. 10A.

FIG. 10B illustrates a partial top perspective view of a rotation section of the testing system according to aspects of this disclosure. The rotation section 922 may include a plurality of conductors associated therewith, for example first conductor 510A and 510B as illustrated by FIG. 10B (e.g., at least partially within a notch 1000 of the rotation section 922 at an outer surface thereof), although additional or fewer conductors may be used in various embodiments. The rotation section 922 may include a body coupling section 1020 configured to couple the rotation section 922 to the body 920 of the testing system 900. The body coupling section 1020 may include at least one notch 1022, for example corresponding to one or more notch(es) 1000. A channel 1024 of the body coupling section 1020 may be configured to permit at least one conductor and/or other element(s) to pass therethrough. For example, in the embodiment illustrated by FIG. 10B, the first conductor 510A and the second conductor 510B are configured to pass through the channel 1024.

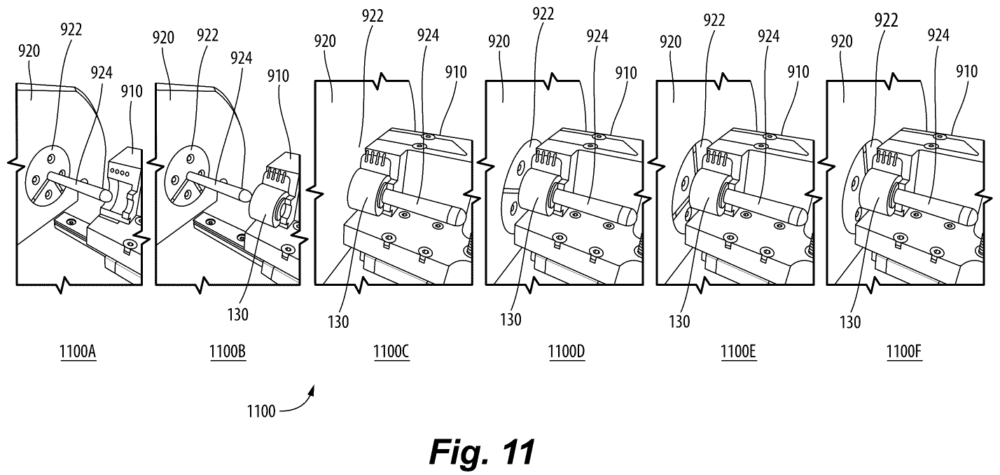

FIG. 11 illustrates a partial view of an embodiment of a sequence of testing a sensor component at a testing system according to aspects of this disclosure. The sequence 1100 can include a first stage 1100A where the nest 910 is not coupled to a sensor component (e.g., CT 130 under test), and the rotation section 922 is in an initial position, with the probe 924 unoccupied. At a second stage 1100B a CT 130 can be coupled to the nest 910. In the second stage 1100B the nest 910 has not been moved along the rail 930 onto the probe 924. At a third stage 1100C, the CT 130 under test can be moved onto the probe 924 to towards the rotation section 922, for example by translating the nest 910 along the rail 930. The rotation section 922 can be rotated 90-degrees as illustrated by the fourth stage 1100D. The rotation section 922 can then be rotated an additional 90-degrees at a fifth stage 1100E. One or more additional or continued rotations may occur, as illustrated by the sixth stage 1100F. One or more sets of measurement data may be obtained during operation of the testing device, for example at one or more of stages 1100A-1100F. Measured data may be obtained, for example, using the nest 910 coupled to the CT 130 under test and the test module 701.

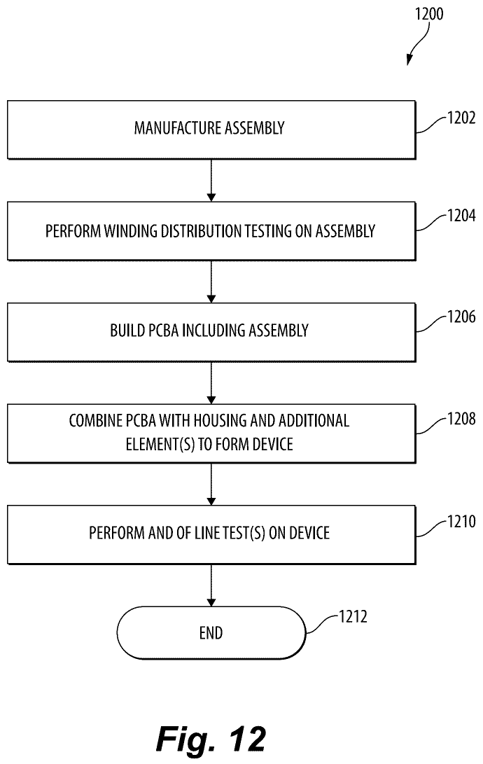

FIG. 12 illustrates an embodiment of a process for testing a sensor component according to aspects of this disclosure. A process 1200 can begin at an operation 1202 where an assembly (e.g., a CT) is manufactured. Winding distribution testing can be performed on the assembly at an operation 1204. A PCBA can be built including the assembly at an operation 1206. The PCBA can be combined with a housing and optionally one or more additional elements to form a device at an operation 1208. One or more end of line tests can be performed on the formed device at an operation 1210 and the process then can end at an operation 1212.

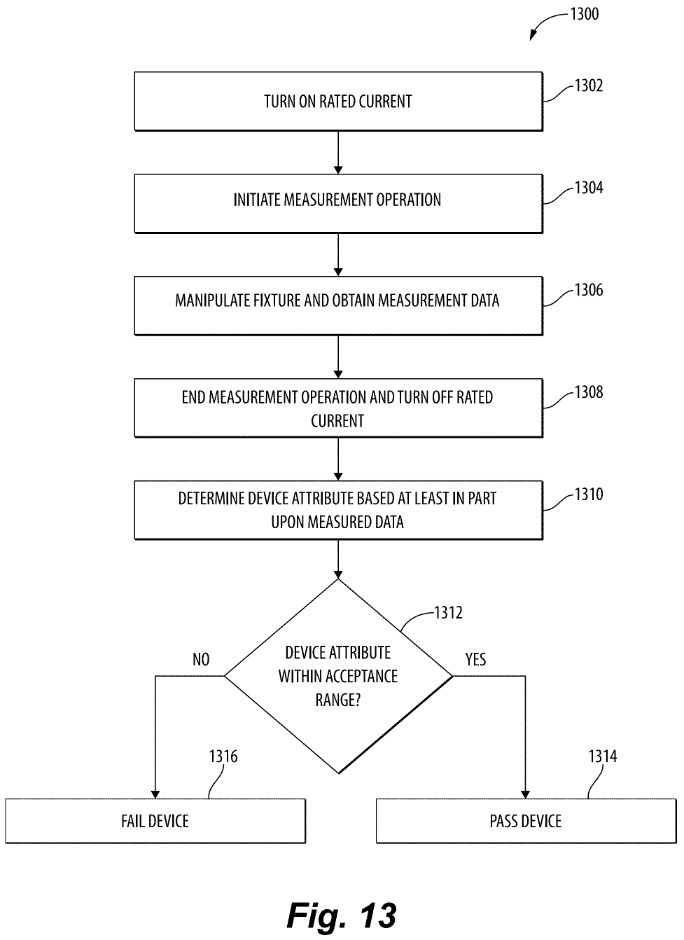

FIG. 13 illustrates an embodiment of a process for determining test performance of a sensor component according to aspects of this disclosure. A process 1300 can begin at an operation 1302 where a rated current is activated. A measurement operation can be initiated at an operation 1304. At least a portion of a testing system can be manipulated (e.g., a probe of the testing system is rotated) at an operation 1306. The measurement operation can be ended at an operation 1308 and the rated current can be turned off. A device attribute can be determined at an operation 1310 based at least in part upon the data measured during the measurement operation. It can be determined at an operation 1312 whether a device attribute is within an acceptable range. If it is determined at the operation 1312 that the device attribute is within an acceptable range, the process can move to an operation 1314 where the device passes. If, however, the device attribute is not within an acceptable range, the process can continue to an operation 1316 where the device is determined to have failed.

FIG. 14 illustrates an embodiment of a waveform generated in association with a sensor component tested according to aspects of this disclosure. The waveform 1400 includes a chart of the output voltage measured during a testing operation on a CT 130. The amplitude of the output voltage may be visualized across time of the testing (e.g., during rotation of the probe). One or more thresholds may be defined, such as an upper threshold 1420A and a lower threshold 1420B corresponding to the waveform 1410. An area between the upper threshold 1420A and the lower threshold 1420B may be referred to as an acceptable range. The amplitude of the waveform 1410 extends beyond both the upper threshold 1420A and the lower threshold 1420B, thus the device under test (e.g., CT 130) may be determined to have failed, and may be scrapped, discarded, reassembled, and/or other remediation or disposal operations may be performed

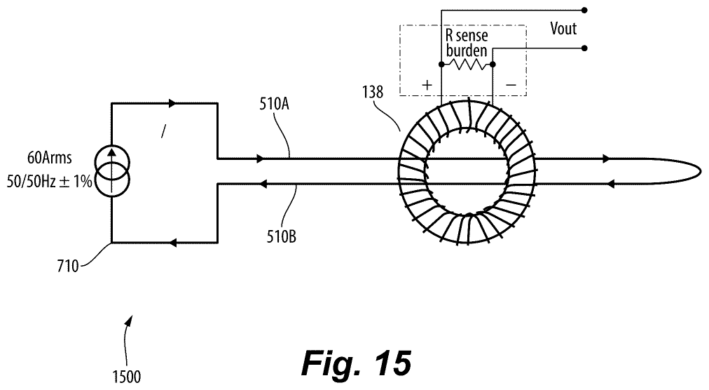

FIG. 15 illustrates a partial diagram of an alternative embodiment of a probe useable with a testing system according to aspects of this disclosure. The structure 1500 includes a partial schematic view of a probe which does not include the first eccentric path L1 or the second eccentric path L2 of the structure 700.

FIG. 16A illustrates an example of a waveform generated in association with a sensor component under test using the current loop of the testing system illustrated by FIG. 15 according to aspects of this disclosure for a CT having moderate winding distribution asymmetry. FIG. 16B illustrates an example of a waveform generated in association with a sensor component under test using the current loop of the testing system illustrated by FIG. 7 according to aspects of this disclosure for a CT having moderate winding distribution asymmetry. As reflected by the side-by-side comparison of FIGS. 16A and 16B, the probe design of FIG. 7 which includes the first eccentric path L1 and the second eccentric path L2 can provide a better reflection of the winding distribution of a CT 130 under test. Although both FIGS. 16A and 16B reflect examples of failed results for the CT 130 under test, the probe design of FIG. 7 including the first eccentric path L1 and the second eccentric path L2 can provide a clearer and more specific representation of the characteristics of the CT 130 over the measurement period.

FIGS. 16A and 16B represent a mechanical rotation of 180 degrees over the shown time span. Certain embodiments of a method can include turning on the rated current, recording output of the CT (e.g., at a sample rate of 50,000 samples per second), rotating the fixture 180 degrees, stopping recording and turning of the rated current, calculating peak RMS voltage, and comparing the peak RMS voltage to a limit to determine whether the CT is passed (e.g., less than limit) or failed (e.g., greater than or equal to the limit).

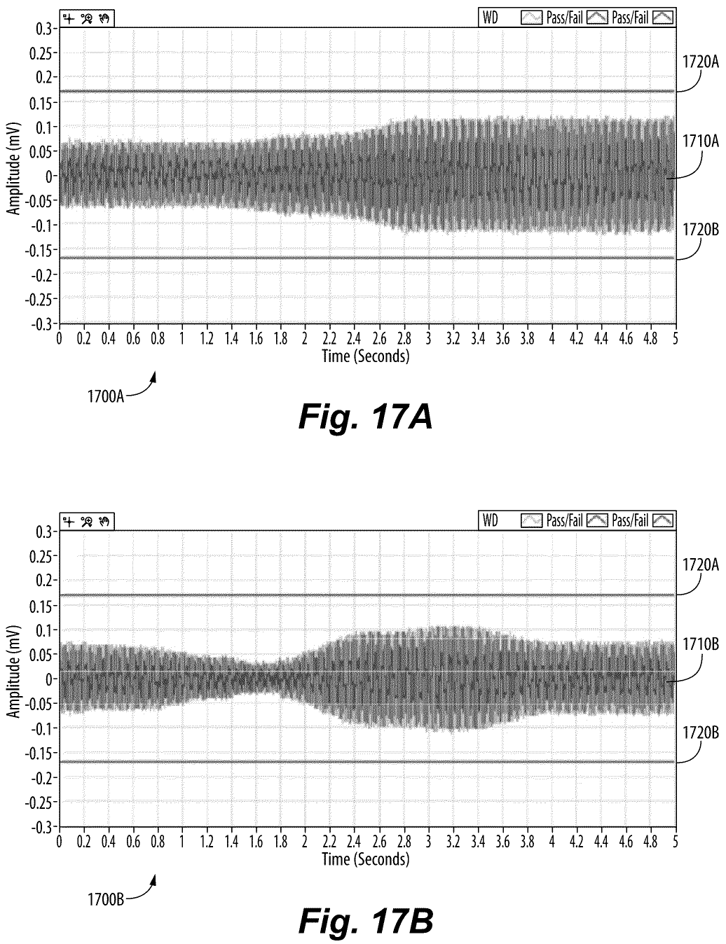

FIG. 17A illustrates an example of a waveform generated in association with a sensor component under test using the current loop of the testing system illustrated by FIG. 15 according to aspects of this disclosure for a CT having low winding distribution asymmetry. FIG. 17B illustrates an example of a waveform generated in association with a sensor component under test using the current loop of the testing system illustrated by FIG. 7 according to aspects of this disclosure for a CT having low winding distribution asymmetry. As reflected by the side-by-side comparison of FIGS. 17A and 17B, the probe design of FIG. 7 which includes the first eccentric path L1 and the second eccentric path L2 provides a better reflection of the winding distribution of a CT 130 under test. Although both FIGS. 17A and 17B reflect passing results for the CT 130 under test, the probe design of FIG. 7 including the first eccentric path L1 and the second eccentric path L2 provides a clearer and more specific representation of the characteristics of the CT 130 over the measurement period.

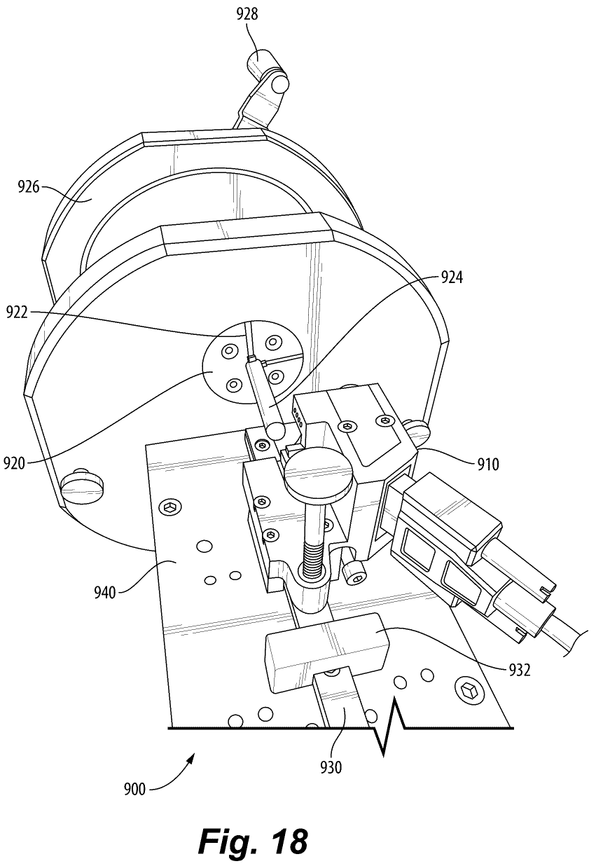

FIG. 18 illustrates a partial raised view of an embodiment of a testing system according to aspects of this disclosure. The testing system 900 may include the features previously described herein, including the nest 910, the body 920, the rotation section 922, the probe 924, the rail 930, and the base 940. The testing system 900 may further include a rear portion 926 of the body, optionally coupleable to a rotation mechanism 928. The rotation mechanism 928 may be any manually and/or electronic element(s) for causing the rotation section 922 and/or probe 924 to rotate and/or translate. Although illustrated as a manual handle in FIG. 18, it should be appreciated that non-manual operation may be provided, for example by or in conjunction with an actuation element (e.g., motor) or other component configured to provide rotation or translation of the rotation section 922 or probe 924, either alone or in combination with one or more manual or electronic elements.

Implementations consistent with this disclosure may provide a system for screening an electronic component. The system may include a device under test, a body having a plurality of conductors, a rotation section, a probe associated with the rotation section, the probe configured to house at least a portion of one or more of the plurality of conductors, and a nest having at least one terminal, the nest configured to couple to the device under test and to permit at least a portion of the probe to pass through an opening of the device under test. The rotation section may rotate the probe within the opening of the device under test. The rotation section may include an eccentric section, which receives at least one of the plurality of conductors and which is configured to be placed adjacent to the device under test during a screening operation. The eccentric section may include a plurality of notches at an outer surface configured to receive at least a portion of at least one of the plurality of conductors. The eccentric section may include at least one groove associated with at least one of the plurality of notches, the at least one groove configured to receive at least a portion of at least one of the plurality of conductors. The plurality of notches may include two notches, and the at least one groove may include two grooves. The system further includes a rail, the rail configured to couple to the nest and further configured to translate movement of the nest relative to the probe. The device may be a current transformer having at least one winding. A voltage associated with at least one winding of the current transformer may be measured as the probe rotates within the opening of the device under test. A rotation mechanism may be coupleable to at least one of the rotation section or the probe, the rotation mechanism configured to cause the probe to rotate or translate relative to the device under test.

According to further aspects of this disclosure, provided is an apparatus for screening a device under test. The apparatus includes a body having a plurality of conductors, a rotation section, a probe associated with the rotation section, the probe configured to house at least a portion of one or more of the plurality of conductors, and a nest having at least one terminal, the nest configured to couple to the device under test. The rotation section may rotate the probe during a screening operation. The rotation section may include an eccentric section configured to receive at least one of the plurality of conductors. The eccentric section may include a plurality of notches at an outer surface configured to receive at least a portion of at least one of the plurality of conductors. The eccentric section may include at least one groove associated with at least one of the plurality of notches, the at least one groove configured to receive at least a portion of at least one of the plurality of conductors. The plurality of notches may include two notches, and the at least one groove may include two grooves. The apparatus may include a rail configured to couple to the nest and further configured to translate movement of the nest relative to the probe.

According to further aspects of this disclosure, provided is a method for screening an electronic component. The method includes manufacturing an assembly, performing wire distribution testing on the assembly, forming a device by building a Printed Circuit Board Assembly (PCBA) including the assembly a combining the PCBA with a housing, and executing an end of line test on the device. The wire distribution testing may include activating a rated current, initiating a measurement operation, obtaining measurement data in relation to the assembly, ending the measurement operation and turning off the rated current, determining a device attribute associated with the assembly, and comparing the device attribute to at least one threshold value to determine whether the assembly is acceptable. Obtaining measurement data in relation to the assembly may include rotating a probe and/or rotation section of testing device within an opening of the assembly while a rated current is passed through at least one conductor within the probe. Obtaining measurement data in relation to the assembly may include obtaining measurement data responsive to an eccentric portion of the probe containing at least one conductor, the eccentric portion of the probe rotating adjacent to the assembly.

In the preceding, reference is made to various embodiments. However, the scope of this disclosure is not limited to the specific described embodiments. Instead, any combination of the described features and elements, whether related to different embodiments or not, is contemplated to implement and practice contemplated embodiments. Furthermore, although embodiments may achieve advantages over other possible solutions or over the prior art, whether or not a particular advantage is achieved by a given embodiment is not limiting of the scope of this disclosure. Thus, the preceding aspects, features, embodiments and advantages are merely illustrative and are not considered elements or limitations of the appended claims except where explicitly recited in a claim(s).

Implementations consistent with this disclosure may provide one or more solutions to problems referenced above and experienced in the field, amongst other problems solved by implementations according to this disclosure. Benefits associated with implementations consistent with this disclosure may include increased reliability of winding distribution and wrap around effects screening for current transformers (CTs). Consistency may also be increased in field performance based at least in part upon the acceptance of only CTs within winding distribution limits.

Implementations consistent with this disclosure may provide numerous benefits, including not requiring a duplicate production current patent that is used for sensor testing. This may be achieved, for example, by the development of a testing platform that is capable of generating a worst-case magnetic flux, which is not required to be specific to a particular Miniature Circuit Breaker (MCB) design. This worst case may be the point where the CT outputs the maximum voltage due to the high winding asymmetry in combination with the position of the conductors passing through it. To determine this, each CT may be tested using the method described herein, by rotating the conductors until a maximum voltage is found at a certain rotation angle. Then this voltage is compared against a defined limit. If the value is below that limit, the CT will pass, otherwise it may be rejected.

Furthermore, no current path switching is required by implementations consistent with this disclosure, based at least in part upon use of a rotating eccentric probe method. Screening operations may be controllable and repeatable with a high confidence level for true rejection of sensor assemblies (e.g., CTs) with high winding asymmetry. An eccentric rotating probe of the type described herein may provide the possibility of finding a highest CT output voltage on a particular position due to the level of winding asymmetry and current path effect. Still further, implementations consistent with this disclosure may provide easy automation implementation for production.

According to aspects of this disclosure, provided are solutions testing platforms that are capable of generating a worst magnetic flux which is not specific to a particular MCB design which may be used to help improve the CT screening process at an early stage of manufacturing/assembly, thereby decreasing time and cost relating to existing methods and systems. The CT screening process may be improved by testing CTs against a worst-case condition. Thresholds can be used to control yields at end line testing. Production current paths do not have to duplicate for CT testing, and a final current path is not required to qualify sensors. Furthermore, the screening process is simplified by implementing a place and test CT sequence.

Unlike existing manufacturing processes which require classification of CTs prior to device assembly, with testing only performed after device assembly, implementations consistent with this disclosure can significantly decrease required investment, sorting, reworking, and scrapping of CTs and assembled devices by preventing early detectable CT device failure conditions at an early stage of manufacturing rather than only at the end of the process.

A winding distribution and current path's electromagnetic influence over a sensor's output voltage can be quantified by screening two-pole toroidal CTs on a device according to this disclosure which replicates the MCB magnetic phenomena. According to aspects of this disclosure, provided is a method for screening circuit breaker toroidal sensor for ground fault applications, for example as a device architecture which generates a magnetic flux equivalent to the one found in a real two-pole MCB circuit path. One or more methods or operations described herein may provide the ability to mitigate ground fault inconsistent detection under handle rated load conditions (e.g., rejection of CTs with high winding asymmetry). Implementations may involve placing a two-pole CT in a fixture, then passing a balanced opposite current through a pair of eccentric rotating conductors to obtain a maximum output voltage on a burden resistor. Then the magnitude of this output voltage may be compared against a defined threshold (e.g., fail/pass criteria).

Embodiments can include any suitable computer hardware and/or software module(s) to perform any suitable function (e.g., as disclosed herein). Any suitable method(s) or portion(s) thereof disclosed herein can be performed on and/or by any suitable hardware and/or software module(s). Any suitable method(s) and/or portion(s) thereof disclosed herein can be embodied as computer executable instructions stored on a non-transitory computer readable medium, for example.

As will be appreciated by those skilled in the art, aspects of this disclosure may be embodied as a system, method or computer program product. Accordingly, aspects of this disclosure may take the form of an entirely hardware embodiment, an entirely software embodiment (including firmware, resident software, micro-code, etc.), or an embodiment combining software and hardware aspects, all possibilities of which can be referred to herein as a “circuit,” “module,” or “system.” A “circuit,” “module,” or “system” can include one or more portions of one or more separate physical hardware and/or software components that can together perform the disclosed function of the “circuit,” “module,” or “system”, or a “circuit,” “module,” or “system” can be a single self-contained unit (e.g., of hardware and/or software). Furthermore, aspects of this disclosure may take the form of a computer program product embodied in one or more computer readable medium(s) having computer readable program code embodied thereon.

Computer program code for carrying out one or more operations for aspects of this disclosure or otherwise related to one or more operations for aspects of this disclosure may be written in any combination of one or more programming languages. Moreover, such computer program code can execute using a single computer system or by multiple computer systems communicating with one another (e.g., using a local area network (LAN), wide area network (WAN), the Internet, etc.). While various features in the preceding are described with reference to flowchart illustrations and/or block diagrams, a person of ordinary skill in the art will understand that each block of the flowchart illustrations and/or block diagrams, as well as combinations of blocks in the flowchart illustrations and/or block diagrams, can be implemented by computer logic (e.g., computer program instructions, hardware logic, a combination of the two, etc.). Generally, computer program instructions may be provided to a processor(s) of a general-purpose computer, special-purpose computer, or other programmable data processing apparatus. Moreover, the execution of such computer program instructions using the processor(s) produces a machine that can carry out a function(s) or act(s) specified in the flowchart and/or block diagram block or blocks.

Block diagrams in the Figures may illustrate the architecture, functionality and/or operation of possible implementations of various embodiments of this disclosure. In this regard, each block in any flowchart or block diagrams may represent a module, segment or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of this disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of this disclosure may be described above with reference to flowchart illustrations and/or block diagrams of methods, apparatus (systems) and computer program products according to embodiments of this disclosure. It will be understood that each block of any flowchart illustrations and/or block diagrams, and combinations of blocks in any flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in any flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified herein.

Those having ordinary skill in the art understand that any numerical values disclosed herein can be exact values or can be values within a range. Further, any terms of approximation (e.g., “about”, “approximately”, “around”) used in this disclosure can mean the stated value within a range. For example, in certain embodiments, the range can be within (plus or minus) 20%, or within 10%, or within 5%, or within 2%, or within any other suitable percentage or number as appreciated by those having ordinary skill in the art (e.g., for known tolerance limits or error ranges).

The articles “a”, “an”, and “the” as used herein and in the appended claims are used herein to refer to one or to more than one (i.e., to at least one) of the grammatical object of the article unless the context clearly indicates otherwise. By way of example, “an element” means one element or more than one element.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.”

Any suitable combination(s) of any disclosed embodiments and/or any suitable portion(s) thereof are contemplated herein as appreciated by those having ordinary skill in the art in view of this disclosure.

The embodiments of this disclosure, as described above and shown in the drawings, provide for improvement in the art to which they pertain. While the subject disclosure includes reference to certain embodiments, those skilled in the art will readily appreciate that changes and/or modifications may be made thereto without departing from the spirit and scope of the subject disclosure.

What is claimed is:

1. A system for screening an electronic component, comprising:
a device under test;
a body having,
a plurality of conductors;
a rotation section;
a probe associated with the rotation section, the probe configured to house at least a portion of one or more of the plurality of conductors; and
a nest having at least one terminal, the nest configured to couple to the device under test and to permit at least a portion of the probe to pass through an opening of the device under test, wherein the rotation section is configured to rotate the probe within the opening of the device under test.

2. The system of claim 1, wherein the rotation section includes an eccentric section, the eccentric section configured to receive at least one of the plurality of conductors, the eccentric section being further configured to be placed adjacent to the device under test during a screening operation.

3. The system of claim 2, wherein the eccentric section comprises a plurality of notches at an outer surface configured to receive at least a portion of at least one of the plurality of conductors.

4. The system of claim 3, wherein the eccentric section further comprises at least one groove associated with at least one of the plurality of notches, the at least one groove configured to receive at least a portion of at least one of the plurality of conductors.

5. The system of claim 4, wherein the plurality of notches comprises two notches, and further wherein the at least one groove comprises two grooves.

6. The system of claim 1, wherein the system further includes a rail, the rail configured to couple to the nest and further configured to translate movement of the nest relative to the probe.

7. The system of claim 1, wherein the device is a current transformer having at least one winding.

8. The system of claim 7, wherein a voltage associated with at least one winding of the current transformer is configured to be measured as the probe rotates within the opening of the device under test.

9. The system of claim 8, further comprising a test module configured to receive voltage signals from the current transformer to determine whether the current transformer is functioning within a set threshold as the prob rotates.

10. The system of claim 1, further comprising a rotation mechanism coupleable to at least one of the rotation section or the probe, the rotation mechanism configured to cause the probe to rotate or translate relative to the device under test.

11. An apparatus for screening a device under test, comprising:
a body having,
a plurality of conductors;
a rotation section;
a probe associated with the rotation section, the probe configured to house at least a portion of one or more of the plurality of conductors; and
a nest having at least one terminal, the nest configured to couple to the device under test, wherein the rotation section is configured to rotate the probe and rotation section during a screening operation.

12. The apparatus of claim 11, wherein the rotation section includes an eccentric section, the eccentric section configured to receive at least one of the plurality of conductors.

13. The apparatus of claim 12, wherein the eccentric section comprises a plurality of notches at an outer surface configured to receive at least a portion of at least one of the plurality of conductors.

14. The apparatus of claim 13, wherein the eccentric section further comprises at least one groove associated with at least one of the plurality of notches, the at least one groove configured to receive at least a portion of at least one of the plurality of conductors.

15. The apparatus of claim 14, wherein the plurality of notches comprises two notches, and further wherein the at least one groove comprises two grooves.

16. The apparatus of claim 11, further comprising a rail, the rail configured to couple to the nest and further configured to translate movement of the nest relative to the probe.

17. A method for screening an electronic component, comprising:
manufacturing an assembly;
performing wire distribution testing on the assembly;
forming a device by building a Printed Circuit Board Assembly (PCBA) including the assembly and combining the PCBA with a housing; and
executing an end of line test on the device.

18. The method of claim 17, wherein the wire distribution testing comprises:
activating a rated current;
initiating a measurement operation;
obtaining measurement data in relation to the assembly;
ending the measurement operation and turning off the rated current;
determining a device attribute associated with the assembly; and
comparing the device attribute to at least one threshold value to determine whether the assembly is acceptable.

19. The method of claim 18, wherein the obtaining measurement data in relation to the assembly includes rotating a probe of testing device within an opening of the assembly while a rated current is passed through at least one conductor within the probe.

20. The method of claim 19, wherein the obtaining measurement data in relation to the assembly includes obtaining measurement data responsive to an eccentric portion of the probe containing at least one conductor, the eccentric portion of the probe rotating adjacent to the assembly during testing.
